(19) United States
(12) Patent Application Publication
(10) Pub. No.: US 2008/0111206 A1
(43) Pub. Date: May 15, 2008

(54) Substrate with Two Sided Doping and Method of Producing the Same

(75) Inventors: Jack I. Hanoka, Brookline, MA (US); Christopher E. Dube, Lexington, MA (US); Carolyn K. Schad, Shrewsbury, MA (US)

Correspondence Address: BROMBERG & SUNSTEIN LLP, 125 SUMMER STREET, BOSTON, MA, 02110-1618, US

(73) Assignee: EVERGREEN SOLAR, INC., Marlborough, MA (US)

(21) Appl. No.: 11/934,592

(22) Filed: Nov. 2, 2007

Related U.S. Application Data
(60) Provisional application No. 60/858,309, filed on Nov. 10, 2006.

(51) Int. Cl. H01L 21/228; H01L 31/058

(52) U.S. Cl. 257/463; 438/548; 257/E31.002; 257/E21.153

(57) ABSTRACT

A method of processing a substrate having first and second surfaces applies a first dopant in liquid form on the first surface of the substrate, and applies a second dopant in liquid form on the second surface of the substrate. The method then causes the first and second dopants to diffuse into the substrate.

### PRIORITY

This patent application claims priority from provisional U.S. patent application No. 60/858,309, filed Nov. 10, 2006, entitled, “IN-LINE PROCESS FOR DOUBLE SIDED DIFFUSION ON SOLAR CELL SUBSTRATES,” and naming Jack I. Hanoka, Christopher Dube, and Carolyn K. Schad as inventors, the disclosure of which is incorporated herein, in its entirety, by reference.

### FIELD OF THE INVENTION

The invention generally relates to doping substrates and, more particularly, the invention relates to improving the electrical efficiency and performance of conductive substrates.

### BACKGROUND OF THE INVENTION

Silicon substrates/wafers are the building blocks of a wide variety of semiconductor devices, such as solar cells, integrated circuits, and MEMS devices. For example, Evergreen Solar, Inc. of Marlboro, Mass. forms solar cells from STRING RIBBON™ silicon wafers fabricated by means of the well-known “ribbon pulling” technique.

To perform their basic function, silicon wafers must be electrically conductive. To that end, conventional processes typically dope the wafer in a prescribed manner, depending on the desired function. For example, when a silicon substrate is formed, it can be doped with, for example, boron or phosphorous, to form either a p-type or n-type bulk substrate. To form semiconductor junctions, conventional diffusion processes first may apply a liquid phase doping material (i.e., opposite to that of the wafer) to the front surface of the wafer, and then cause the dopant to diffuse into the wafer to form a p-n junction. Among other things, these semiconductor junctions can be part of active circuitry implemented by the wafer (e.g., transistors or diodes). The dopant also may form conductive paths between circuit components, and passive circuitry (e.g., resistors or capacitors).

In addition to providing the desired electrical properties, liquid phase doping provides an added benefit; namely, it aids in removing impurities that reduce the electrical efficiency of the wafer. Specifically, as background, a silicon wafer typically is formed from a silicon melt having a certain concentration of impurities, such as metals. These metals, which undesirably often become part of the wafer at some concentration, reduce electrical efficiency. To improve electrical efficiency, those skilled in the art often perform “gettering” processes on the wafer—i.e., processes that attempt to reduce this impurity concentration in the wafer.

Liquid phase doping material reduces the noted impurity concentration by getting metallic impurities in the wafer. Specifically, when heated, the impurities are drawn toward the outer surface of the diffused layer to form metal precipitates at the interface of the doping material and wafer, thus concentrating the impurities in a prescribed region of the wafer. Subsequent processes then may remove the impurities from that region.

Gettering in this manner, however, may not be sufficient to remove impurities from silicon wafers having relatively high impurity concentrations. Accordingly, this gettering technique primarily benefits wafers having relatively low impurity concentrations, i.e., wafers that generally are more expensive than those having higher impurity concentrations.

### SUMMARY OF THE INVENTION

In accordance with one embodiment of the invention, a method of processing a substrate having first and second surfaces applies a first dopant in liquid form on the first surface, and applies a second dopant in liquid form on the second surface. The method then causes the first and second dopants to diffuse into the substrate.

The first and second dopants may be substantially the same types of dopant. For example, both the first and second dopants may be n-type dopants. Alternatively, the first and second dopants may be different types of dopants. For example, the first dopant may be an n-type dopant, while the second dopant may be a p-type dopant.

In some embodiments, the first dopant diffuses into the substrate to form a semiconductor junction. Specifically, the first dopant may be either a p-type dopant or an n-type dopant, while the second dopant is a different type of dopant than that of the first dopant (e.g., in a manner similar to the example above, the first dopant may be an n-type dopant, while the second dopant may be a p-type dopant). Among other things, the second dopant may form a backside electrode on the substrate.

An in-line diffusion process may cause the dopants to diffuse into the substrate. In that case, the method may support the substrate on a conveyor belt apparatus that moves the substrate to the interior of a furnace. The first dopant may form a coating (on the first surface) that contacts the belt apparatus to mechanically isolate the substrate from the belt apparatus.

During diffusion, the method may heat the substrate to cause impurities from the substrate to integrate with the first and second dopants, thus forming first and second precipitate layers. The method further may remove at least a portion of the first precipitate layer, and at least a portion of the second precipitate layer.

Some embodiments may invert/rotate the substrate after applying the first dopant to the first surface of the substrate, but before applying the second dopant the second surface of the substrate. Moreover, among other things, the substrate may be formed from a silicon ribbon crystal-type substrate.

In accordance with another embodiment of the invention, after providing a substrate having a first surface and a second surface, a doping method applies a first dopant to the first surface, and a second dopant to the second surface. The first dopant and second dopant are different types of dopants (e.g., one is n-type and the other is p-type). The method then processes the substrate and dopants to cause the dopants to diffuse into the substrate.

The first dopant may diffuse into the substrate to form a semiconductor junction, while the second dopant may diffuse into the substrate to form a backside electrode. The method also may electrically isolate the semiconductor junction.

In accordance with other embodiments of the invention, an apparatus has a substrate with a front surface and a back surface. The front surface is doped by a first dopant that is either p-type or n-type. Conversely, the back surface is doped by a second dopant that is the opposite type of the first dopant. For example, if the front surface is doped by an n-type dopant, then the back surface is doped by a p-type dopant.

Among other types, the substrate may be formed from a ribbon-crystal type wafer.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a semiconductor wafer that may be doped in accordance with illustrative embodiments of the invention.

FIG. 2 schematically shows an illustrative solar panel that may be formed from the semiconductor wafer shown in FIG. 1.

FIG. 3A schematically shows a cross-sectional view of the wafer shown in FIG. 1 in accordance with a first embodiment of the invention.

FIG. 3B schematically shows a cross-sectional view of the wafer shown in FIG. 1 in accordance with a second embodiment of the invention.

FIG. 4 schematically shows an embodiment of an in-line doping apparatus that may dope wafers in accordance with illustrative embodiments of the invention.

FIG. 5 schematically shows additional details of the in-line doping apparatus shown in FIG. 4. Specifically, selected portions of the housing are moved from the drawing of FIG. 4 to expose interior components.

FIG. 6 shows a process of doping wafers in accordance with illustrative embodiments of the invention.

FIG. 7A schematically shows a wafer at step 600 of the process of FIG. 6.

FIG. 7B schematically shows a wafer after one of its surfaces is coated with a dopant material.

FIG. 7C schematically shows a wafer after both of its surfaces are coated with a dopant material.

FIG. 8 schematically shows an illustrative transfer assembly for placing wafers on the flipper of FIG. 9.

FIG. 9 schematically shows a flipper for rotating wafers in accordance with illustrative embodiments of the invention.

### DESCRIPTION OF ILLUSTRATIVE EMBODIMENTS

In illustrative embodiments, a method more efficiently getters a substrate (hereinafter “wafer”) by doping both its front and back sides/surfaces. For example, some embodiments may dope the front surface of a p-type wafer with an n-type liquid dopant, and the back surface with a p-type liquid dopant. Alternatively, as another example, rather than doping the back surface with a p-type dopant, the method may dope the back surface with an n-type liquid dopant. In either case, when heated, the dopants simultaneously draw metallic impurities toward both surfaces, thus forming metal precipitates at the respective surfaces. As a result, wafers initially having more impurities can have substantially the same impurity concentration as wafers initially having fewer impurities.

Moreover, when implemented as an in-line doping process, illustrative embodiments effectively shield the wafer from contaminants on the moving belt of the doping apparatus. Accordingly, illustrative embodiments reduce another source of impurities in the wafer.

Finally, in addition to improving gettering, illustrative embodiments facilitate more design flexibility by providing multiple, functional doped surfaces of a single wafer. For example, one surface of the wafer may have a backside electrode, while the opposite surface may have active circuitry. Details of illustrative embodiments are discussed below.

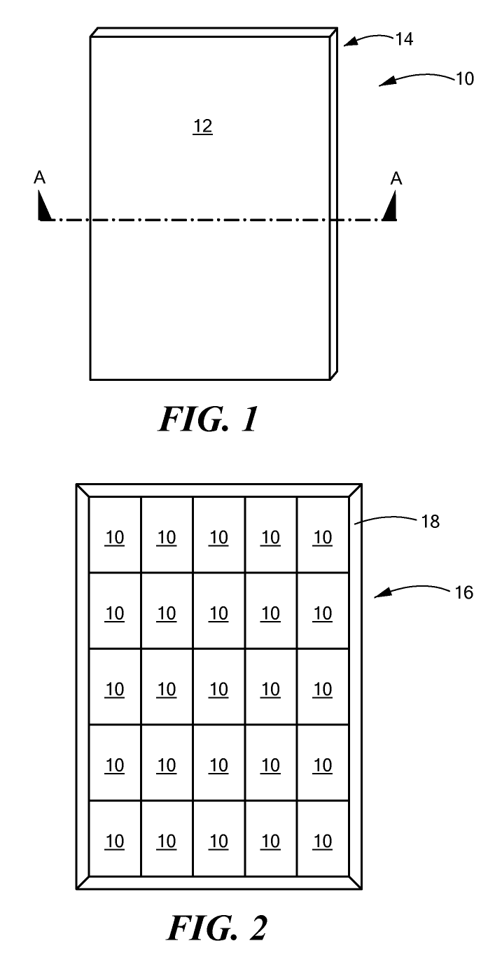

FIG. 1 schematically shows a front view of a wafer 10 doped in accordance with illustrative embodiments of the invention. The wafer 10 may be any kind of conventional doped wafer, such as a silicon wafer formed by the well-known Czochralski crystal pulling process, or conventional ribbon crystal pulling processes. For purposes of this discussion, the wafer 10 is a ribbon crystal-based silicon wafer, such as those produced by Evergreen Solar, Inc. of Marlborough Mass. For additional details of ribbon crystals and processes of forming ribbon crystals, see U.S. Pat. Nos. 4,594,229; 4,627,887; 4,661,200; 4,689,109; 6,090,199; 6,200,383; and 6,217,649. Of course, discussion of a ribbon crystal is intended to be illustrative and thus, not intended to limit a number of other embodiments.

In a manner similar to other ribbon-crystal based wafers, this wafer 10 has a generally rectangular shape and a relatively large surface area on its front and back surfaces 12 and 14. For example, the wafer 10 may have a width of about 3 inches, and a length of about 6 inches. As known by those skilled in the art, the length can vary significantly depending upon the process used to form it. In some processes, the length depends upon where an operator cuts the ribbon crystal (not shown) as it is growing. In automated processes, the length may be based upon a prespecified location on a ribbon crystal during the growth process.

In addition, the width can vary depending upon the separation of its two strings (not shown) passing through a silicon melt in a crucible (also not shown). Accordingly, discussion of specific lengths and widths are illustrative and not intended to limit various embodiments the invention. In like manner, the thickness of the wafer 10 varies and is very thin relative to its length and width dimensions. For example, the wafer 10 can have a thickness of between about 50 microns and about 300 microns.

FIG. 2 schematically shows use of the ribbon crystal-based silicon wafer 10 in a solar panel 16. Specifically, among other things, the solar panel 16 has a frame 18 for mounting a two dimensional array of silicon wafers 10 that cooperate to generate electricity from a source of light. Of course, a solar panel 16 is merely one of a number of different uses for a ribbon crystal-based silicon wafer.

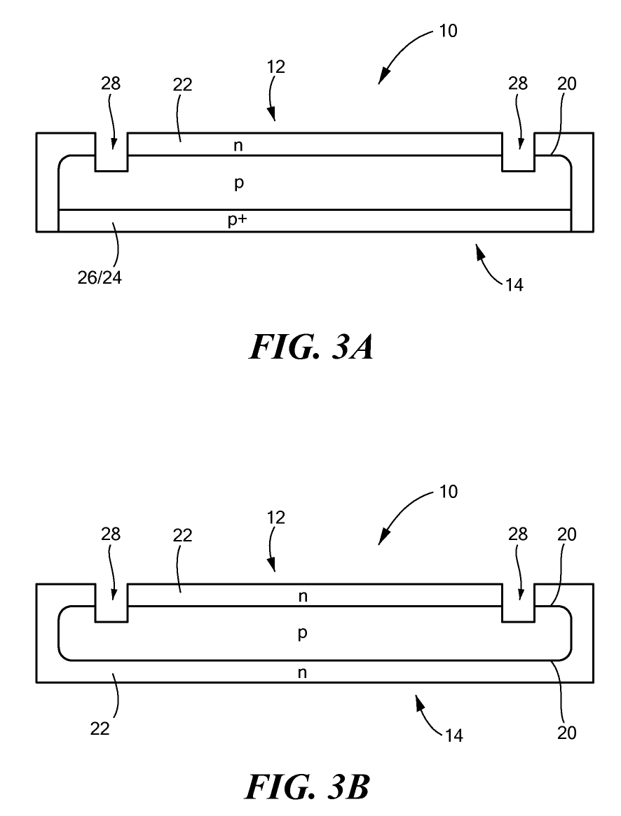

FIG. 3A schematically shows a cross-sectional view of one embodiment of the wafer 10 of FIG. 1 across line A-A. As a preliminary matter, it should be noted that FIGS. 1, 2 and 3A (as well as FIG. 3B, among others) are not drawn to scale. Instead, those figures should be considered schematic drawings for descriptive purposes only.

Specifically, in this embodiment, the wafer 10 has a semiconductor junction 20 near its front surface 12, and a backside electrode 24 formed on its back surface 14. To that end, in the example shown, the wafer 10, which may be p-type doped, forms the semiconductor junction 20 with an n-type region 22 near the front surface 12. This semiconductor junction 20 therefore may be further processed to form functional circuit elements, such as transistors and diodes.

In addition to being near the front surface 12 of the wafer 10, this n-type region 22 also extends downwardly toward the back surface 14 along the side of the wafer 10. The inventors have noticed, however, that extending the doping region in this manner often stains the opposite surface. Applications requiring more aesthetically pleasing wafers therefore should avoid this practice. Accordingly, some embodiments do not extend the n-type region 22 along the side of the wafer 10 toward its back surface 14. Instead, such embodiments may simply have an n-type region 22 with a generally planar shape that is generally parallel to the front surface 12.

In a corresponding manner, the wafer 10 forms the backside electrode 24 with a p-plus-type doped region 26 on and near its back surface 14. A pair of isolation trenches 28 electrically isolate the semiconductor junction 20 from the backside electrode 24. The trenches 28 may be filled with an insulating material, such as nitride, or remain unfilled.

In a manner similar to the embodiment shown in FIG. 3A, the embodiment of FIG. 3B also forms a semiconductor junction 10 near its front surface 12. In contrast to the embodiment of FIG. 3A, however, this embodiment forms a second semiconductor junction near its back surface 14. In fact, this semiconductor junction effectively integrates with that formed by the top surface and thus, may extend contiguously around the wafer 10. Accordingly, the second semiconductor junction serves as an additional source for forming circuitry. Filled or unfilled isolation trenches 28 also may electrically isolate the two semiconductor junctions.

It should be noted that these cross-sectional views are simplified for descriptive purposes only. Accordingly, conventional processes can vary the doping concentrations and distribution across the wafer 10 by using, among other things, masking techniques.

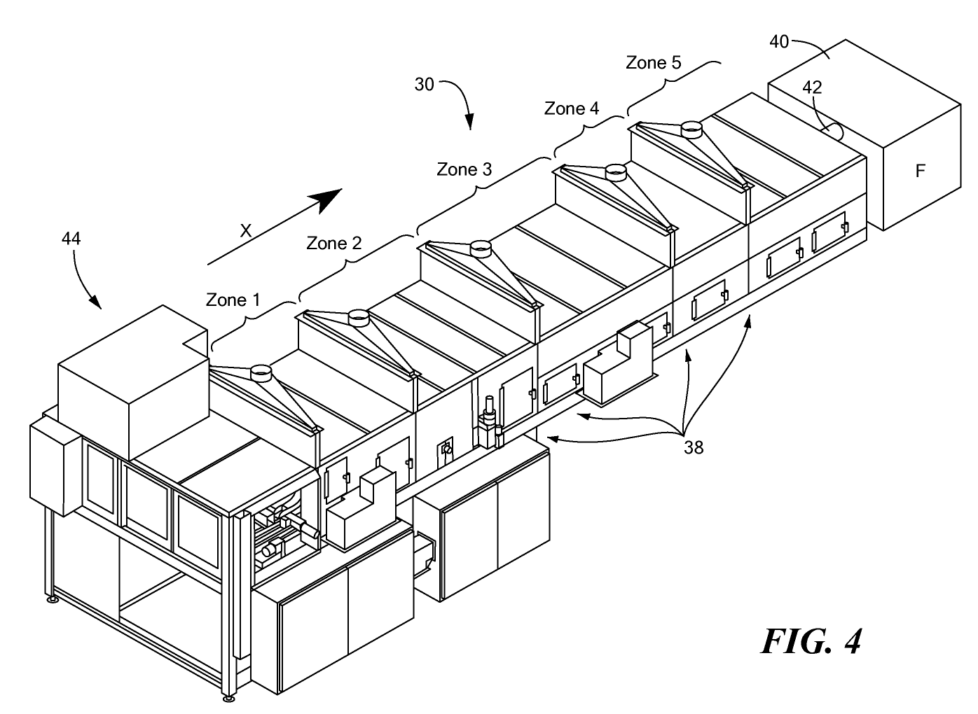

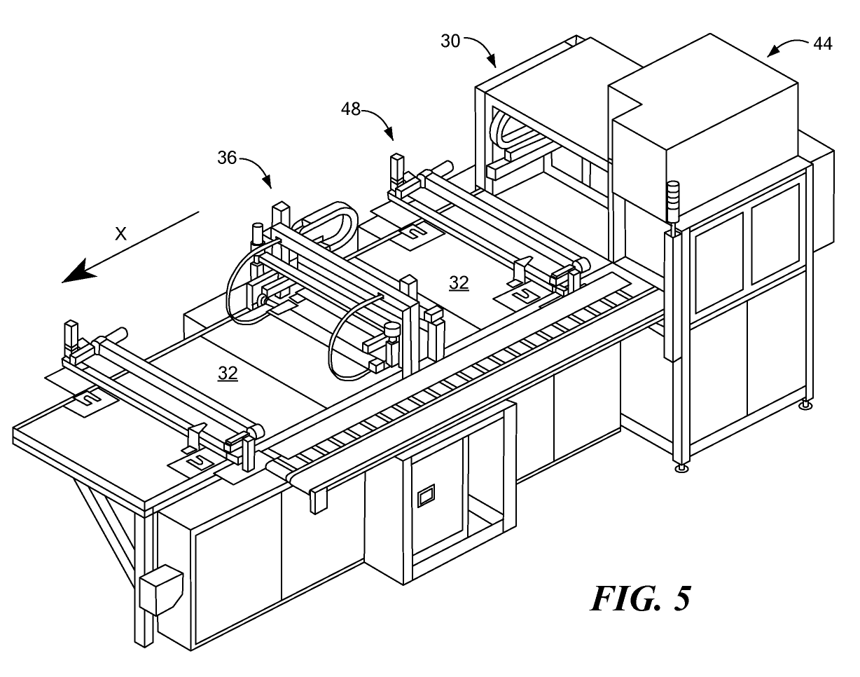

Additional handling generally is required to dope the two large surfaces 12 and 14 of the wafer 10. As known by those skilled in the art, however, many wafers are very fragile. Those skilled in the art therefore often prefer to minimize wafer handling to reduce breakage. Accordingly, a specialized apparatus 30 was developed to more gently handle wafers 10 during the illustrative doping process. To that end, FIG. 4 schematically shows a multi-zone, in-line doping apparatus 30 (also referred to as an “in-line diffusion” apparatus 30) for doping both large surfaces 12 and 14 of the wafer 10. FIG. 5 schematically shows the same in-line doping apparatus 30 from its other side. It should be noted that FIG. 5 does not show all of the zones shown in FIG. 4.

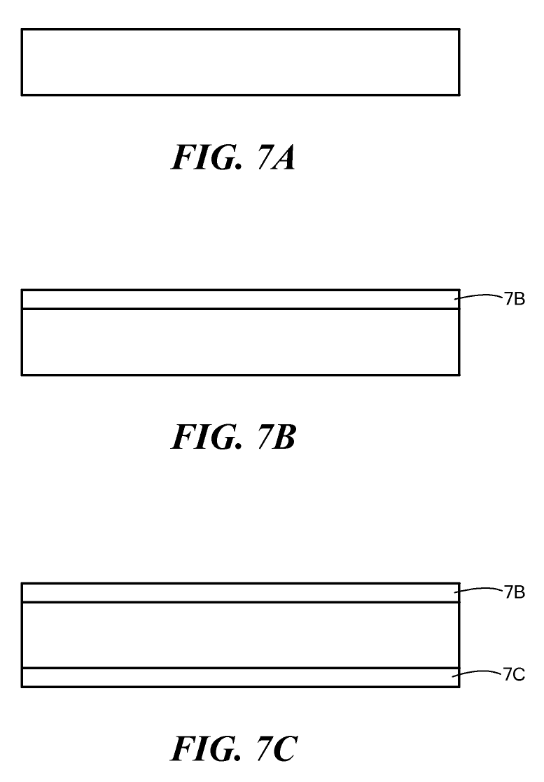

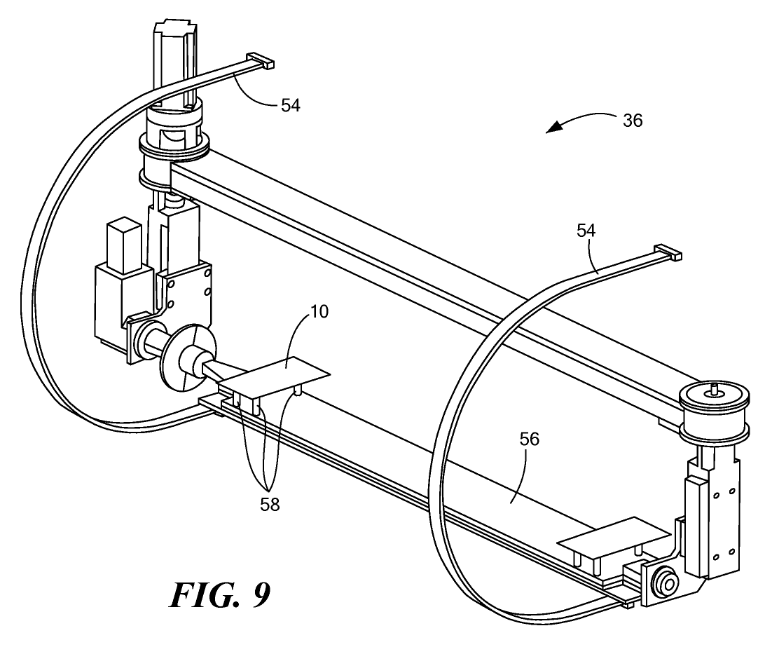

More particularly, the doping apparatus 30 has a plurality of zones (also referred to as “chambers”) for serially processing the wafer 10 in accordance with illustrative embodiments of the invention. Each zone may be separated by a plenum that also exhausts humidity within the apparatus 30. The internal termination of each plenum illustratively is asymmetrical to prevent the exhaust stream from lifting wafers from a moving, low temperature belt 32. After passing through a wafer loading portion 44, the wafer 10 is positioned on the noted low temperature belt 32 so it can move through the remaining zones of the apparatus 30. The diffusion apparatus 30 may have the following zones:
A first zone (Zone 1) for applying a first doping source material (i.e., often referred to for simplicity as a first dopant) in liquid form to the back surface 14 of the wafer 10.
A second zone (Zone 2) for causing the first doping source material first to gel, and then subsequently dry to form a coating 46A (see FIG. 7B) on the back surface 14 of the wafer 10. Zone 2 also has a flipper 36 (see FIG. 9, discussed below) for rotating the wafer 10 180 degrees, thereby exposing the front surface 12 of the wafer 10.
A third zone (Zone 3) for applying a second doping source material (i.e., a second dopant) in liquid form to the front surface 12 of the wafer 10.
A fourth zone (Zone 4) for causing the second doping source material to gel on the front surface 12 of the wafer 10.
A fifth zone (Zone 5) for drying the second doping source material on the front surface 12 of the wafer 10, thus forming a coating 46B (see FIG. 7C) on the front surface 12.

A plastic housing 38 encases each of these zones to protect the wafer 10 from the environment and facilitate internal processes. As noted above, the housing 38 has plenums that effectively form a plurality of chambers for separating the different zones. For descriptive purposes, FIG. 5 shows the apparatus 30 with this housing 38 removed to display more details of the interior.

After passing through Zone 5, the wafer 10 moves into a high temperature belt furnace 40 that facilitates gettering and diffusion of the dopant into the wafer 10. To that end, the furnace 40 has a high temperature belt 42 formed from material capable of withstanding high temperatures, such as about 800 to 900 degrees Centigrade. For example, the high temperature belt 42 may be formed from a metal, and, to minimize handling, be positioned to gently receive the wafer 10 from the low temperature belt 32, which may be formed from a liquid absorbing material, such as a plastic-backed cloth web or paper.

It should be noted that the diffusion apparatus 30 is discussed as processing one wafer 10 at a time. This description is for simplicity purposes only. To increase yields, various embodiments are expected to process a plurality of wafers 10 in parallel along parallel wafer channels. Accordingly, the low temperature and high temperature belts 32 and 42 are sized to transport a two dimensional array of wafers 10. For example, the belts 32 and 42 may be sized and configured to transport 10 parallel columns of wafers 10 through the diffusion apparatus 30 in the direction shown by arrow “X” in FIGS. 4 and 5.

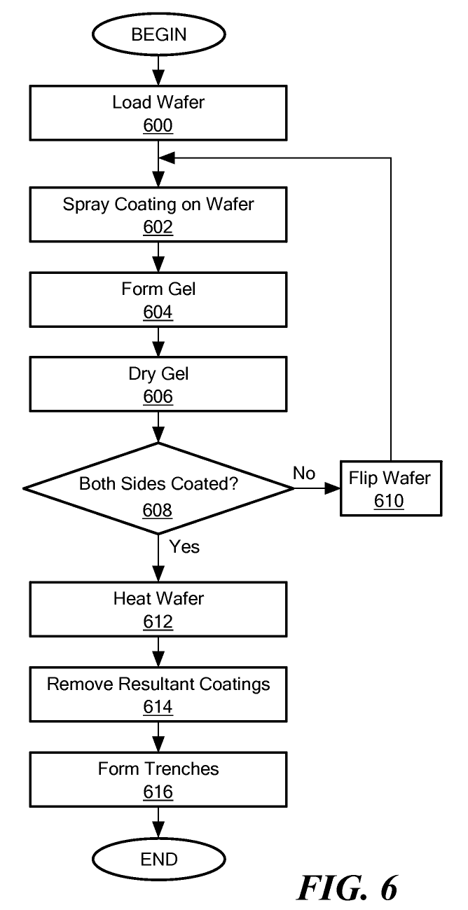

FIG. 6 shows some basic details of an illustrative process for doping the wafer 10 using the apparatus 30 shown in FIGS. 4 and 5. As noted above, this process both dopes and getters the wafer 10 to improve wafer quality (e.g., reduce supply costs), and enables production of functional elements on both surfaces 12 and 14 of the wafer 10. It should be noted that for simplicity, this process includes some but not all steps of the entire process. For example, this process may include quality-control steps that are not discussed. Accordingly, those skilled in the art should understand that this process may be used in conjunction with additional processing steps.

The process begins at step 600 by loading the wafer 10 into the doping apparatus 30 (see FIG. 7A for a cross-sectional view of the wafer 10 at this point). To that end, the wafer 10 may be mechanically loaded from a container onto the wafer loading portion 44 of the doping apparatus 30. Accordingly, at this point in the process, the low temperature belt 32 fully supports the wafer 10.

Moreover, as suggested above, the wafer 10 illustratively is pre-doped before beginning this process. For example, the wafer 10 may be pre-doped with an n-type dopant or a p-type dopant. For discussion purposes, the wafer 10 discussed below is predoped with a p-type dopant.

After being loaded onto the low temperature belt 32, the wafer 10 moves to Zone 1, which, as noted above, sprays a dopant in liquid form onto the back surface 14 of the wafer 10 (step 602). To that end, Zone 1 may apply the dopant in a conventional manner, such as by using a conventional spin-on process. This process illustratively may be within a chamber having a controlled humidity level of between about 35 and 65 percent from a set point, and have a length of about 42 inches. Note that when on the low temperature belt 32, the wafer 10 may travel at a constant speed, such as about 18 inches per minute. Alternative embodiments vary the speed to provide more flexibility with the processing parameters.

The process may use any of a variety of commercially available dopants, such as phospholicate polymers or phosphoric acid. For example, when producing the apparatus shown in FIG. 3B (i.e., a back surface 14 with a related semiconductor junction), the back side dopant source may include phosphoric acid that can be applied as a mist, as described in greater detail below. Alternatively, when producing the apparatus shown in FIG. 3A (i.e., a back surface 14 with a backside electrode 24), the back side dopant source may include a boron-based material, which also can be applied as a mist.

Illustrative embodiments dilute the dopant with an appropriate solvent, such as ethanol or iso-propanol, to form a sol. The choice of solvent depends on the desired viscosity of the dopant solution. A highly diluted solution should provide a thin, uniform layer that can be rapidly dried. Among other things, rapid drying minimizes the likelihood that dopant will bleed onto the front surface 12 of the wafer 10, which can cause uneven gettering or staining. As noted above, however, some embodiments permit the dopant to bleed in this manner to the respective opposite surface.

Some embodiments have an ultrasonic spray device (not shown) that can be reciprocated transverse to the path of the moving wafer 10 to form a substantially uniform liquid coating. In some embodiments, the liquid dopant can be fed under atmospheric pressure or near atmospheric pressure by gravity, or by a suitable low pressure positive displacement type metering pump. For example, the output pressure of the pump can be between about 16-20 PSI, and the spray device can be an ultrasonic spray head (e.g., distributed by Sono-Tek of Milton, N.Y.). In some implementations, the noted spray head transversely reciprocates across the wafer 10 at a rate of about 48 strokes per minute and sprays the dopant at a rate of about 12.6 milliliters per minute.

Uniformity of coverage of the wafer 10 is directly related to the droplet size of the liquid dopant—smaller droplets generally produce more uniform coatings. Reciprocation frequency, pulsing frequency of the spray head, temperature, surface tension, density, and humidity, among other things, can affect the size of the droplets sprayed on the surface. Specifically, higher pulsing frequencies generally produce smaller average droplet sizes, which generally follow a Gaussian distribution. For example, a 120 kHz pulsing frequency may generate a median diameter for water of about 20 microns. If needed, alcohol can be added to reduce surface tension, thus further reducing droplets sizes (e.g., to a median size of about 12 microns).

Modification of various parameters, such as increasing the pulsing frequency to the megahertz range, can further reduce the size of the droplets. For example, droplets of 1 micron or less can be achieved. In some embodiments, the droplets can be applied in a nitrogen atmosphere to reduce surface tension and thus, further improve uniformity of the coating. Droplet sizes in the range of about 1-100 microns should be achievable.

It should be noted that discussion of specific sizes, parameters, materials, etc . . . are for discussion purposes only and thus, not intended to limit various other embodiments. For example, rather than using spray devices, alternative embodiments use one or more rollers to apply the liquid dopant onto the relevant surface 12 or 14 of the wafer 10. Moreover, alternative embodiments may process the front surface 12 first, or both surfaces 12 and 14 at about the same time.

The process then continues to step 604, in which the liquid coating forms a gel. Specifically, the sprayed-on dopant forms a thin film as it a cross-links on the back surface 14 of the wafer 10. In illustrative embodiments, Zone 2 executes this portion of the process, and may have a temperature of between about 52 and 58 degrees Centigrade. The humidity level in this zone may be uncontrolled.

While in Zone 2, the process continues to step 604 by drying the gel to form a hard dopant coating 46A on the back side 14 of the wafer 10. At this point, the dopant 1) has not yet diffused into the wafer 10 and 2) has not yet formed metallic precipitates that promote gettering.

The process then determines at step 608 if both surfaces 12 and 14 of the wafer 10 have been coated. If not (i.e., only one side—the back side 14—is coated, as shown in FIG. 7B), then the process moves to step 610, which, still within Zone 2, inverts/rotates (i.e., flips) the wafer 10 180 degrees so that the front surface 12 now faces up and the now hard coating 46A on the back surface 14 rests on the belt 32. As noted above, however, many wafers are fragile and must be gently inverted/rotated to maintain their structural integrity.

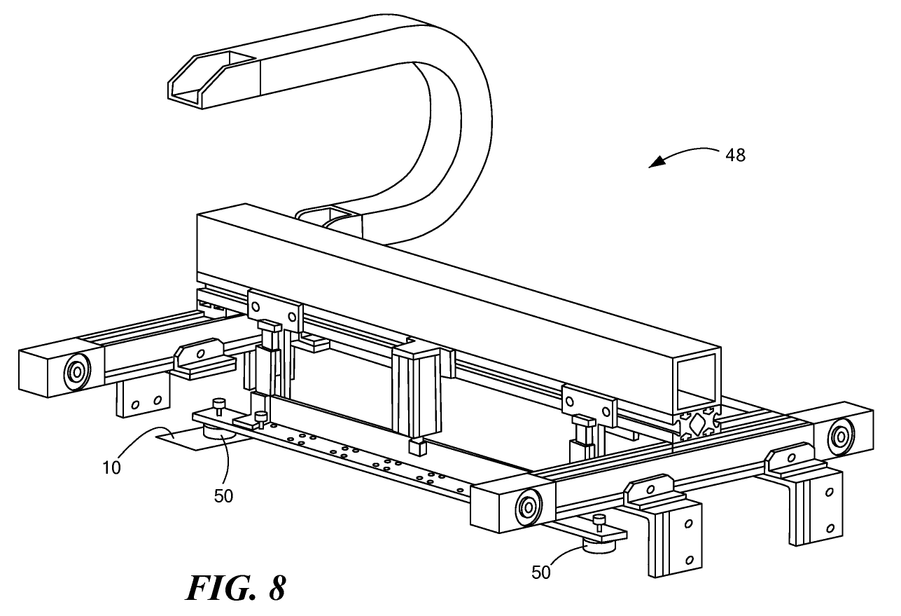

The doping apparatus 30 thus has specialized handling and flipping devices that accomplish this goal. Specifically, as shown in FIGS. 5 and 8, Zone 2 has a transfer assembly 48 for moving the wafer 10 from the low temperature belt 32 onto the prior noted flipper 36 (shown in FIGS. 5 and 9). To those ends, the transfer assembly 48 has a Bernoulli vacuum pick-up 50 that applies a suction/vacuum to the dry coating 46A on the back surface 14 of the wafer 10. For example, the Bernoulli vacuum pick-up 50 may be formed from a metal annular component and receive the vacuum from an external source. Although this discussion relates to a single wafer 10, this process can be applied to multiple parallel silicon wafers 10. FIG. 8 thus shows an additional Bernoulli vacuum pickup for such a purpose.

To transfer the wafer 10, the transfer assembly 48 moves in a direction generally parallel to the belt 32 to a position just above the wafer 10. At that point, the transfer assembly 48 lowers to almost contact or gently contact the coating 46A, and applies its vacuum, through the Bernoulli pick-ups 50, to grasp the wafer 10. The transfer assembly 48 then upwardly again, and then in a direction that is generally parallel with the belt 32 to a position that is aligned with three suction pads on the flipper 36 (see FIG. 9). In illustrative embodiments, the suction pads are NOMATHANE™ vacuum cups (distributed by Annver Corporation of Hudson, Mass.), which are silicone-free vacuum suction cups that are very pliable and said to not leave invisible ghost marks on the wafer 10.

The flipper 36 has, among other things, flexible vacuum lines 54 for applying a vacuum through the vacuum cups 52, and a rotating member 56 for rotating the wafer 10 180 degrees. Accordingly, after aligning with the three suction cups 52 on the flipper 36, the transfer assembly 48 stops supplying the vacuum through its Bernoulli vacuum pick-ups 50, which gently positions the wafer 10 on the vacuum cups 52. The transfer assembly 48 then moves upwardly, away from the vacuum cups 52, and then back to its original position (i.e., its position before it grasped the wafer 10).

The flipper 36 applies a vacuum through the vacuum cups 52 to secure the wafer 10 during rotation. After it secures the wafer 10, the entire flipper 36 moves upwardly to provide enough clearance for the rotating member 56 to rotate the wafer 10. After the rotating member 56 rotates 180 degrees, the entire flipper 36 moves downwardly, very close to the belt 32, and releases its vacuum to again (gently) position the wafer 10 on the low temperature belt 32. Accordingly, at this point in the process, the coating 46A on the back surface 14 of the wafer 10 rests on the belt 32, while the exposed front surface 12 faces upwardly (as noted above).

Continuing from step 610, the process repeats step 602, 604, and 606 for the front surface 12 of the wafer 10. However, in this iteration, the process performs each step in a different zone. Specifically, by breaking up the process in this manner, illustrative embodiments perform these steps slower and more deliberately than in the previous steps in an attempt to more uniformly apply the liquid dopant.

Accordingly, looping back to step 602, the process applies a coating of an n-type dopant, such as phosphoric acid, in a substantially similar manner to that described above. One difference from the application applied to the back surface 14 is that this zone/chamber is much longer than Zone 1. For example, this zone may be about 72 inches (compared with 42 inches in Zone 1). In addition, this zone may have a humidity said at about 35 to 48 percent from a set point.

After Zone 3 applies the dopant, Zone 4 causes the liquid to gel in a 36 inch long chamber having a humidity range of between about 35 and 48 percent from a set point (step 604). The wafer 10 then moves with the belt 32 from Zone 4 to the next serial chamber, Zone 5, which dries the gel in a manner similar to that discussed above (step 606). Again, unlike Zone 2 but like Zone 3 and Zone 4, Zone 5 has a controlled humidity range and is about 54 inches long. For example, Zone 5 may have a humidity range of between about 29 percent and 41 percent from a set point. It should be reiterated that discussion of specific humidity ranges, temperatures, and lengths is merely illustrative of certain embodiments and thus, should not limit various other embodiments. In fact, some embodiments may combine various zones/chambers or separate Zone 2 into multiple chambers.

Returning to step 608, if both surfaces 12 and 14 are coated (see FIG. 7C), the process moves to step 612, which heats the wafer 10 in a prescribed manner to both getter the wafer 10 and cause the dopant to diffuse into the wafer 10. The furnace 40 may be any conventional furnace used for this purpose, such as an infrared belt furnace, that subjects the wafer 10 to high temperatures (e.g., between about 800 and 900 degrees Centigrade). As noted above, the (high temperature) belt 42 of the furnace 40 is separate from the low temperature belt 32 and must be capable of withstanding high temperatures. The two belts 32 and 42 are positioned so that the wafer 10 gently moves from the low temperature belt 32 onto the high temperature belt 42 without outside intervention.

During early experiments of this technology, the inventors discovered what they felt was a previously unappreciated problem; namely, that the high temperature belt 42 significantly contaminated the wafer 10. This effect was more apparent in higher purity wafers 10. After further experimentation and determining the extent of this problem, the inventors further discovered that positioning some kind of barrier between the high temperature belt 42 and wafer 10 should mitigate this problem. Such a barrier should both block migration of the contaminants and yet be capable of withstanding the high temperatures. Accordingly, the inventors solved this newly discovered problem by using the noted dried gel coating 46A on the back surface 14 of the wafer 10 (i.e., formed by the first pass of step 606), which rests upon the high temperature belt 42. This coating 46A should suffice to both block migration of contaminants and withstand high temperatures within the furnace 40.

As noted above, however, the primary purpose of this step is to both getter the wafer 10 and promote diffusion of the dopant into the wafer 10. Accordingly, the wafer 10 passes through the furnace 40 at a prespecified rate that causes both dry coating layers 46A and 46B to diffuse into the wafer 10, which, in turn, causes impurities to migrate toward the surfaces (i.e., gettering). In illustrative embodiments, the impurities combine with the dried gel coatings 46A and 46B on both surfaces 12 and 14 to form metal precipitate coatings (also referred to for simplicity by reference numbers 46A and 46B). Consequently, this process effectively transforms the dried gel coatings 46A and 46B into respective hard coatings/surfaces 46A and 46B. For example, the front surface 12 may form a phosphosilicate surface (if phosphorous were the dopant), which will be removed in a subsequent step (discussed below). If a boron based material (e.g., borosilicate) were the dopant (e.g., the back surface 14), then the impurities form a borosilicate glass surface. These precipitate surfaces now contain many of the impurities that formerly were within the wafer 10, thus significantly reducing the concentration of contaminants within the wafer 10 itself.

The inventors were surprised at the effectiveness of gettering the wafer 10 from both surfaces 12 and 14 using a liquid dopant. Among other reasons, it was the inventors' understanding that those skilled in the art at the time of the invention believed that gettering (using liquid dopant) from only one surface 12 or 14 would remove a sufficient amount of the impurities from the wafer 10. In other words, the inventors believed that those skilled in the art did not appreciate the benefits of gettering from both surfaces 12 and 14. Moreover, there were motivations against taking this approach because of the increased handling requirements. The inventors therefore acted contrary to these motivations to achieve what they considered unappreciated but significantly improved results. Accordingly, using the disclosed processes, one skilled in the art now can use less expensive, lower purity wafers to produce higher purity wafers with semiconductor junctions and/or enhanced doping portions (e.g., backside electrodes).

After heating the wafer 10, the process continues to step 614, which removes the resulting hardened coatings 46A and 46B from the two surfaces 12 and 14 of the wafer 10. For example, the wafer 10 may be treated with a dilute HF acid to remove the resultant coatings 46A and 46B (which may be considered to be a glass layer in some instances). As a result, this step effectively completes removal of many impurities from the wafer 10.

In some instances, the semiconductor junction 20 on the front surface 12 may be electrically connected with the backside electrode 24 of FIG. 3A or other semiconductor junction of FIG. 3B. Accordingly, conventional processes may, if necessary, form the isolation trenches 28 to electrically isolate these portions. For example, laser or wet etch processes may form the trenches 28. Those skilled in the art can isolate the junction in a number of other ways. For example, some embodiments may, among other ways, 1) completely etch off the back side of the surface doped layer, 2) plasma etch the sides of the wafer 10, 3) sand off the sides of the wafer 10, or 4) diamond dicing saw the wafer 10 to remove the wafer sides.

In addition to the benefits described above, various embodiments also enable one skilled in the art to dope the two larger surfaces 12 and 14 of a wafer in opposite manners. For example, the front surface 12 may be doped with an n-type dopant, while the back surface 14 may be doped with a p-type dopant, or vice versa. Of course, various embodiments also enable one skilled in the art to dope the opposite surfaces of the wafer 10 in the same manner (e.g., both surfaces 12 and 14 doped with p-type or n-type dopants).

Although the above discussion discloses various exemplary embodiments of the invention, it should be apparent that those skilled in the art can make various modifications that will achieve some of the advantages of the invention without departing from the true scope of the invention. For example, although both surfaces 12 and 14 of the wafer 10 may be doped, it is not necessary to form functional components on both surfaces 12 and 14. In addition, each surface can be doped at much different times and do not necessarily have to be doped in the short sequential manner described. For example, after doping the front surface 12, alternative embodiments may store the wafer 10. At a later time, the back side 14 of the wafer 10 can be doped.

What is claimed is:

1. A method of processing a substrate having first and second surfaces, the method comprising:
applying a first dopant in liquid form on the first surface of the substrate;
applying a second dopant in liquid form on the second surface of the substrate; and
causing the first and second dopants to diffuse into the substrate.

2. The method as defined by claim 1 wherein the first dopant and the second dopant are substantially the same type of dopant.

3. The method as defined by claim 1 wherein the first dopant and the second dopant are different types of dopants.

4. The method as defined by claim 1 wherein the first dopant diffuses into the substrate to form a semiconductor junction.

5. The method as defined by claim 4 wherein the first dopant is either a p-type dopant or an n-type dopant, the second dopant being a different type of dopant than that of the first dopant.

6. The method as defined by claim 5 wherein the second dopant forms a backside electrode.

7. The method as defined by claim 1 wherein causing comprises an in-line diffusion process, the method further comprising supporting the substrate on a conveyor belt apparatus that moves the substrate to the interior of a furnace.

8. The method as defined by claim 7 wherein causing causes the first dopant to form a coating on the first surface, the coating contacting the belt apparatus to mechanically isolate the substrate from the belt apparatus.

9. The method as defined by claim 1 wherein causing comprises heating the substrate to cause impurities from the substrate to integrate with the first and second dopants, integration of the impurities and dopants forming first and second precipitate layers, the method further comprising removing at least a portion of the first precipitate layer, the method further comprising removing at least a portion of the second precipitate layer.

10. The method as defined by claim 1 further comprising inverting the substrate after applying the first dopant to the first surface of the substrate and before applying the second dopant to the second surface of the substrate.

11. The method as defined by claim 1 wherein the substrate comprises a silicon ribbon crystal-type substrate.

12. The method as defined by claim 1 wherein applying a first dopant comprises spraying the first dopant in liquid form on the first surface of the substrate, further wherein applying a second dopant comprises spraying the second dopant in liquid form on the second surface of the substrate.

13. A doping method comprising:
providing a substrate having a first surface and a second surface;
applying a first dopant to the first surface;
applying a second dopant to the second surface, the first dopant and second dopant being different types of dopants; and
processing the substrate and dopants to cause the dopants to diffuse into the substrate.

14. The method as defined by claim 13 wherein the first dopant diffuses into the substrate to form a semiconductor junction, the second dopant diffusing into the substrate to form a backside electrode.

15. The method as defined by claim 14 further comprising electrically isolating the semiconductor junction.

16. The method as defined by claim 13 wherein applying a first dopant and applying a second dopant comprises processing the substrate and dopants using an in-line diffusion process.

17. The method as defined by claim 13 wherein applying the first dopant comprises spraying the first dopant on the first surface.

18. A solar cell formed in accordance with the process of claim 13.

19. An apparatus comprising:
a substrate having a front surface and a back surface,
the front surface being doped by a first dopant that is either p-type or n-type,
the back surface being doped by a second dopant that is the opposite type of the first dopant.

20. The apparatus as defined by claim 19 wherein the first dopant is an n-type dopant and the second dopant is a p-type dopant.

21. The apparatus as defined by claim 19 wherein the first dopant forms a semiconductor junction with the substrate, the second dopant forming a backside electrode with the substrate.

22. The apparatus as defined by claim 21 wherein the semiconductor junction is electrically isolated from a backside electrode.

23. The apparatus as defined by claim 21 wherein the substrate comprises a ribbon crystal-based silicon wafer.
